(19) United States
(12) Patent Application Publication
(10) Pub. No.: US 2003/0048205 A1
(43) Pub. Date: Mar. 13, 2003

(54) 3D electronic data input device with key mapping card

(76) Inventor: Junru He, West Windsor, NJ (US)

Correspondence Address: Junru Ite, 6 Eastern Dr., West Windsor, NJ, 08550, US

(21) Appl. No.: 10/214,783

(22) Filed: Aug. 8, 2002

Related U.S. Application Data
(60) Provisional application No. 60/311,501, filed on Aug. 10, 2001.

(51) Int. Cl. H03M 11/00; H03K 17/94

(52) U.S. Cl. 341/26; 341/22

(57) ABSTRACT

A 3D electronic data input device with a key mapping card which changes from the prior 2 dimensions layout to 3 dimensions layout, has input keys and a mouse mounted on different sides of the keyboard. It also has electronic circus and connection devices. The key mapping card plays critical role to help users to find needed keys. There are several different sizes of the said keyboards to accommodate different hand sizes. The keyboard can hold and even be integrated with electronic device such as PDA.

### BACKGROUND OF THE INVENTION

1. Field of the Invention

This invention relates to electronic data input devices, and particularly, to hand controlled electronic data input keyboard for PDA, cellular phones, computers, TV, and other electronic devices.

2. Prior Art

All previous works can be categorized into three categories:

First category, keyboards used for desktop computers and other electronic devices. These keyboards all apply 2 dimensions layout, meaning all keys are put on same side of a keyboard. The standard keyboard requires two hands to input data and it is too big to carry around.

Another problem is that the traditional keyboards have to be put on a support surface and users need to sit.

The third problem is that traditional keyboards cause physical injuries because users have to be in certain sitting position which hurts back and neck.

There are some efforts to put keys on top and bottom sides of keyboard such as U.S. Pat. Nos. 5,949,401, 5,410,333, and 6,127,949. All of them create difficulty for users to find out which key they should press for a given letter if they forget the layout. All of them cannot hold PDA. They fail to utilize the space on sides of keyboards. And they have to be used in restricted circumstances, such as help of support surface or arm.

Second category: voice recognition device. In terms of physical size, it is the smallest and very flexible. This device can also help reduce physical injuries because it doesn't require special sitting position. However, besides the accuracy issue associated with the device, this device cannot be used in most occasions because users will make a lot of noise when they are doing input.

The last category is the hand writing which is used in all PDAs. As we all know, the writing speed is very slow.

To accommodate the needs of PDA, interactive TV, cellular phone and other model electronic devices, a new keyboard needs following features:

1. It can be operated efficiently without being put on a surface so that a user can use it in any circumstances, such as traveling, in bus/car, in meeting, sitting on sofa, laying down on bed, etc.

2. It is portable, meaning the size is small enough to be put into pocket.

3. Input speed is at least as fast as traditional desktop keyboard This means that it is easy to find out keys and all fingers are used.

### OBJECTIVES AND SUMMARY OF THE MENTION

The current data input device, keyboard, is same as the keyboard on the mechanic typewriter. It is designed for use in very restricted environment: it has to be put on a hard surface and users have to sit. This was fine for mainframe and personal computers. However, the new generation of electronic devices such as PDA and cellular phones require, on top of fast data input speed, input devices can be used in any circumstances, and easy to be carried around. Integration of TV, computer and Internet creates demand for input device which can be conveniently used while sitting on a couch

The first objective of the present invention, therefore, is to create a new electronic keyboard which allows users to have full flexibility in terms of body position and working environment.

The 2nd object of the present invention to provide a keyboard, which allows user easily to find keys that they want to press.

The 3rd object of the present invention, therefore, is to create a new electronic keyboard which keys are laid out in 3 dimensions, meaning the keys are put on different sides of a board or pad, or put on different pieces of said device and the said pieces can be assembled in such a way to allow fingers operate in 3 dimensions.

The 4th object of the present invention, therefore, is to create a new electronic keyboard which can be used by one or two hands in any occasions such as walking, driving, meeting, etc.

The 5th object of the present invention to provide a keyboard which is convertible so that its size can be reduced so small so that it can be easily carried around.

The 6th object of the present invention to provide a keyboard which allows users to use their fingers in comfort and efficient way so that the input speed is same as a full size keyboard.

The 7th object of the present invention to provide a keyboard which generates as many alphanumeric characters and symbols as a full size keyboard without interaction among non thumb fingers.

The 8th object of the present invention to provide a keyboard which combines keyboard and mouse functions together.

The 9th object of the present invention to provide a keyboard which lets user to sit/stand in any positions to prevent physical injuries.

The 10th object of the present invention to provide a keyboard which allows user to use two hands and one hand if he/she chooses to do so.

The 11th object of the present invention to provide a two hand controlled keyboard which allows users to operate by single hand if one of the two hands cannot be used.

The last objective is to change a PDA to a true palm size computer.

In order to achieve these objects, a 3D electronic data input device with a key mapping card which changes from the prior 2 dimensions layout to 3 dimensions layouts, has input keys mounted on different sides of the keyboard, if necessary, even two different keyboards, a mouse on the side, and electronic circus. The key mapping card plays critical role to help users to find needed keys. The keys associated with thumb are on one side and the keys associated with non-thumb fingers are on different sides of the keyboard. There are at least 1 keys associated with thumb, which are called thumb-keys. There is at least one key associated with each non-thumb finger. There are several different sizes of the said keyboards to accommodate different hand sizes.

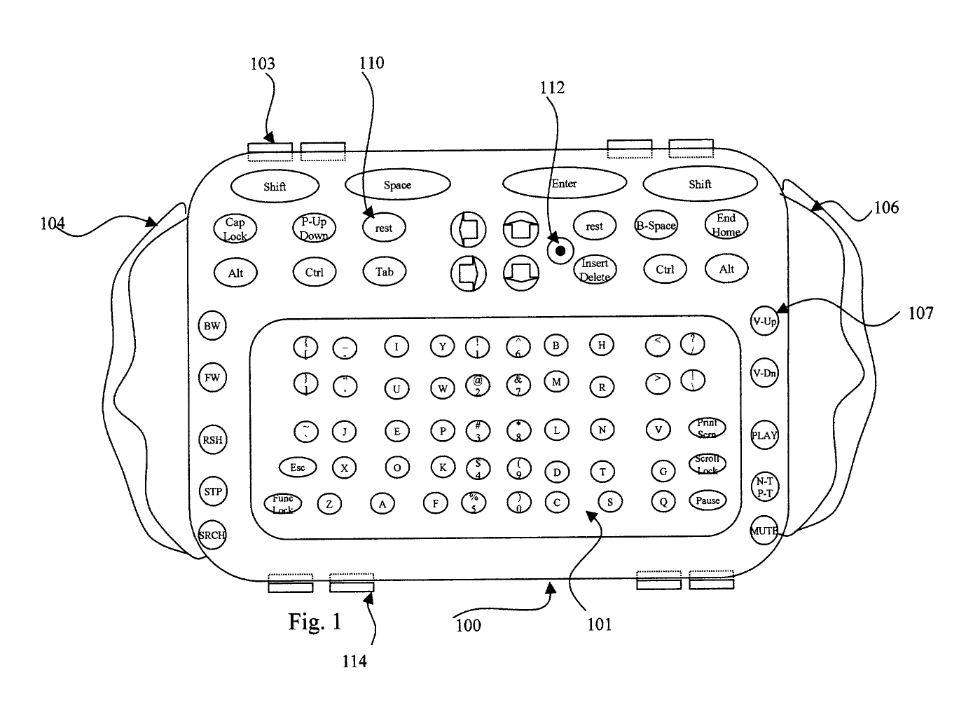

FIG. 1 is front view of the 3D device. The keys shown on the front are controlled by both thumbs. The keys shown on the sides can be controlled by index fingers, thumbs, or other fingers.

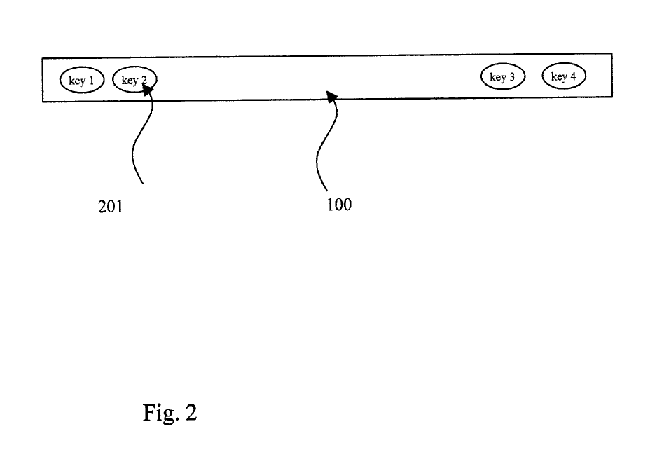

FIG. 2 is the top side view of the keyboard in FIG. 1.

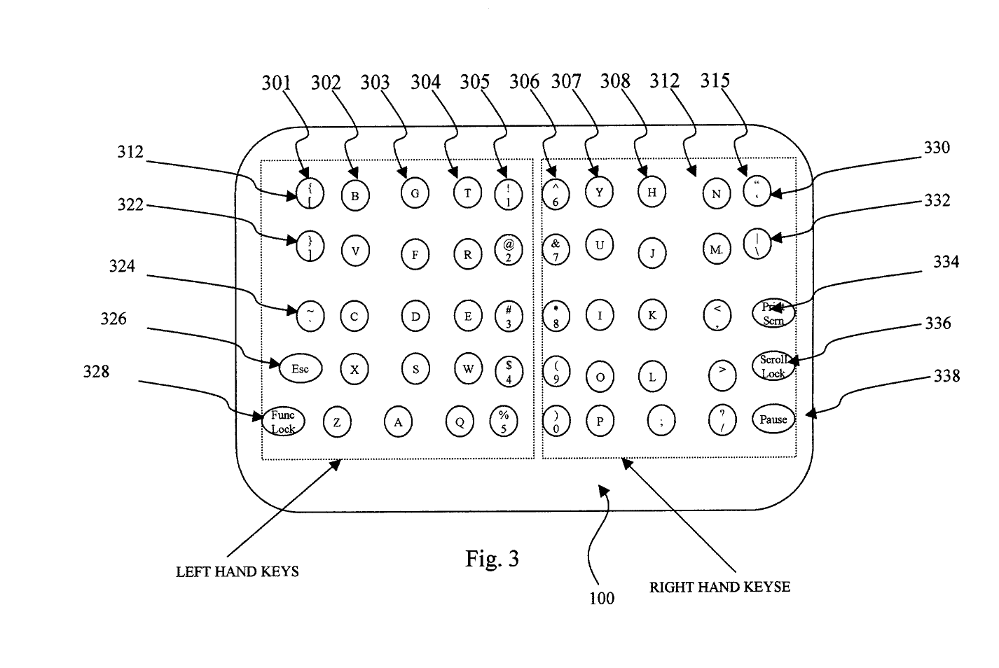

FIG. 3 is back view of the device in FIG. 1. There are two sets of keys. One set are controlled by left hand non-thumb fingers and the other set are controlled by right hand non-thumb fingers.

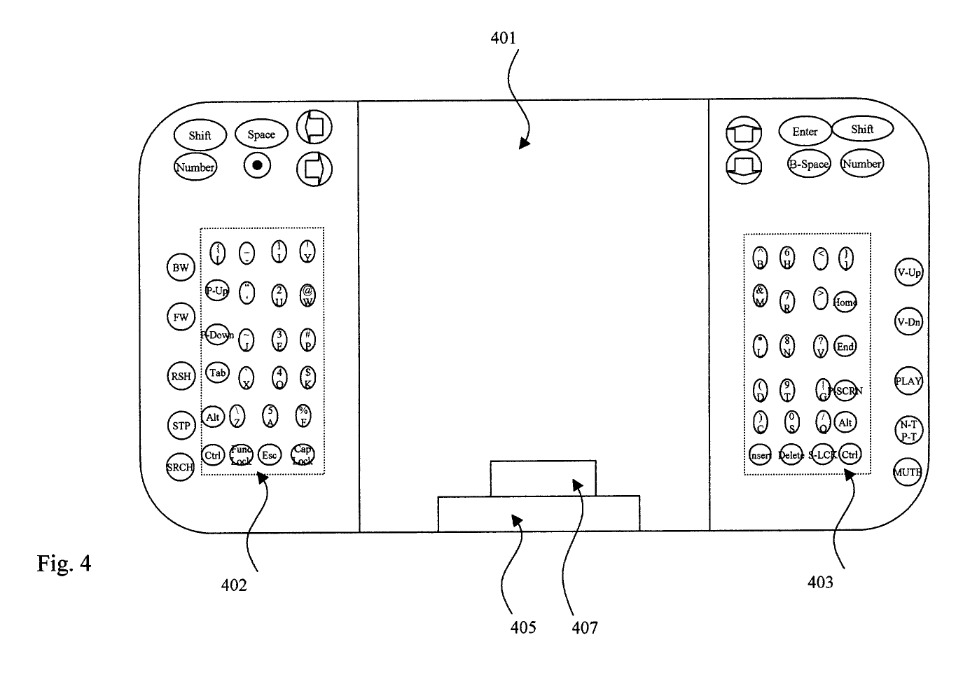

FIG. 4 is front view of the 3D device with space in the middle for holding a PDA.

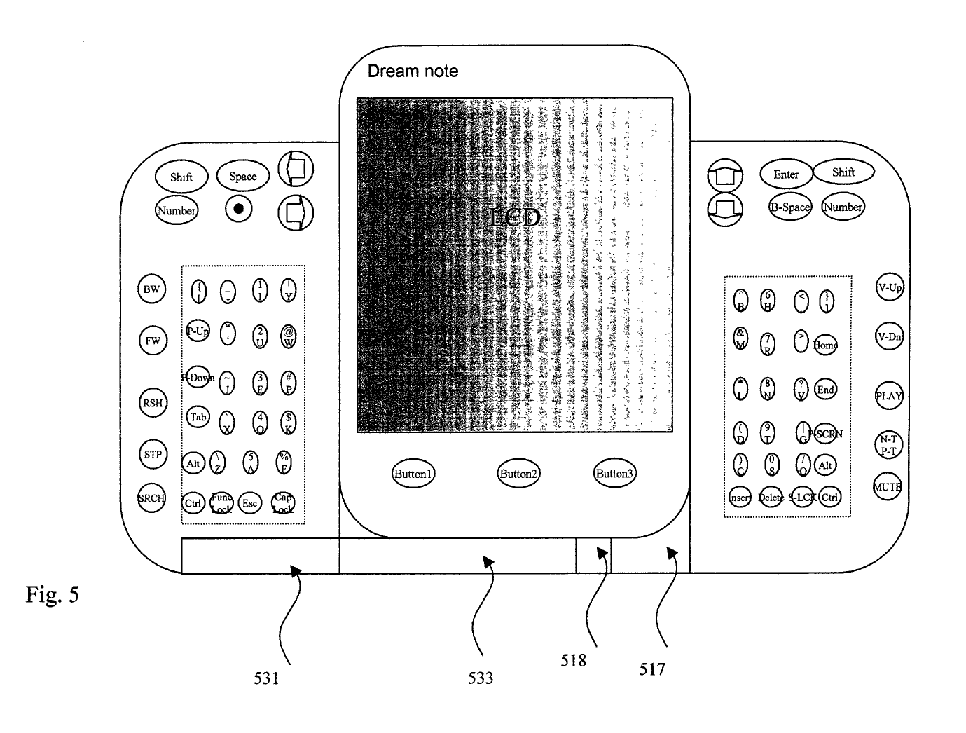

FIG. 5 is same as FIG. 4 with a PDA mounted in the middle.

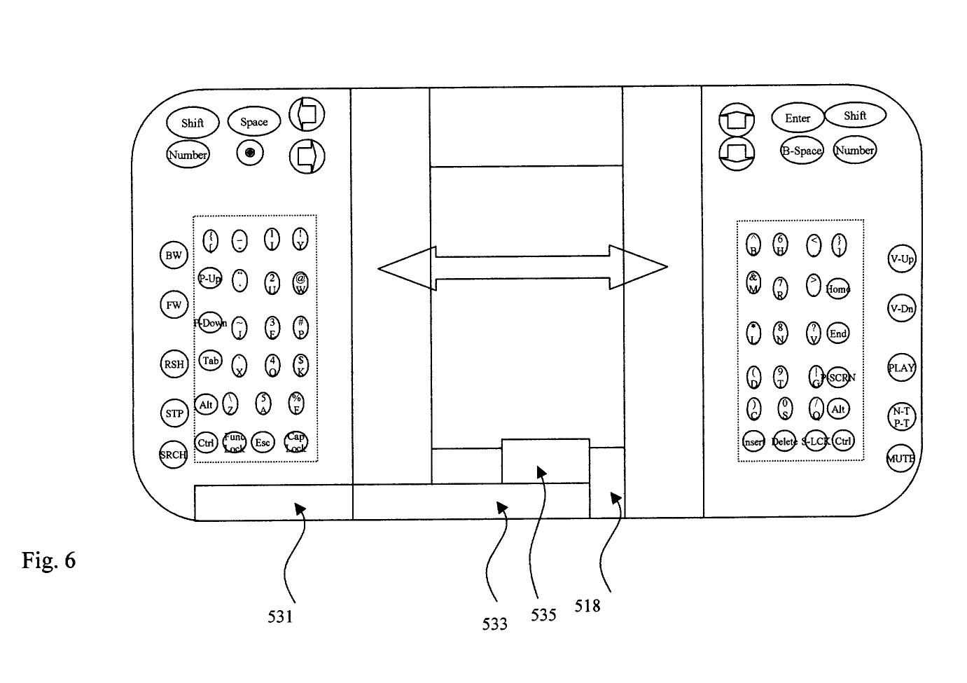

FIG. 6 is front view of the 3D device which has two moving parts which can be pulled apart towards each side. Once pulled apart, as shown in FIG. 6, the middle space can hold a PDA. It also can be pushed in to make the keyboard size small. It is also convertible.

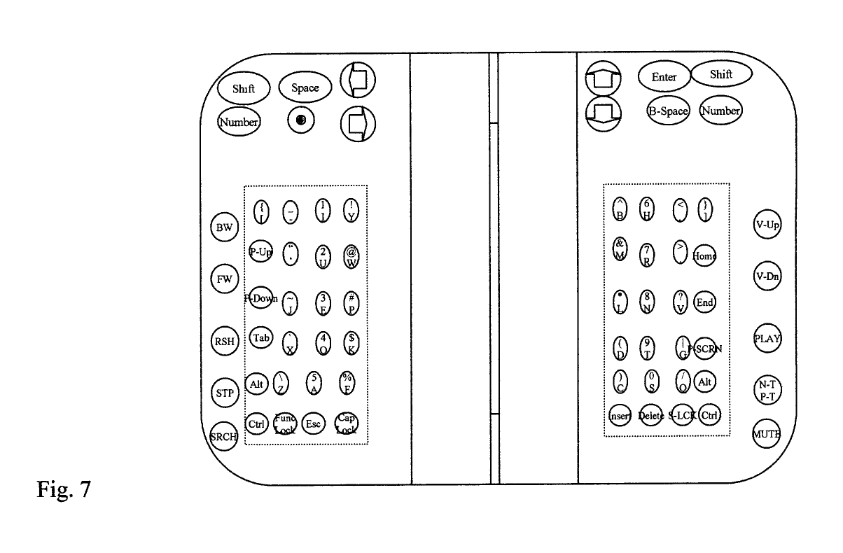

FIG. 7 is same as FIG. 6. It is shown the status when the keyboard is pushed in.

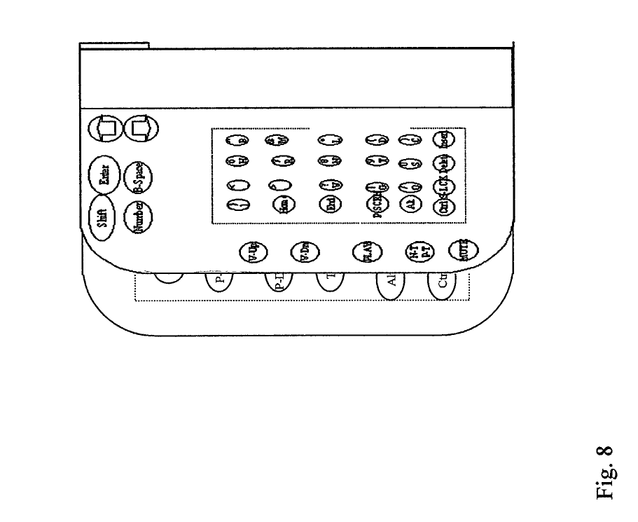

FIG. 8 is same as FIGS. 6 and 7, which shows the status when the keyboard is converted. is front view of the 3D device for two hand use which is integrated with PDA with compact key layout.

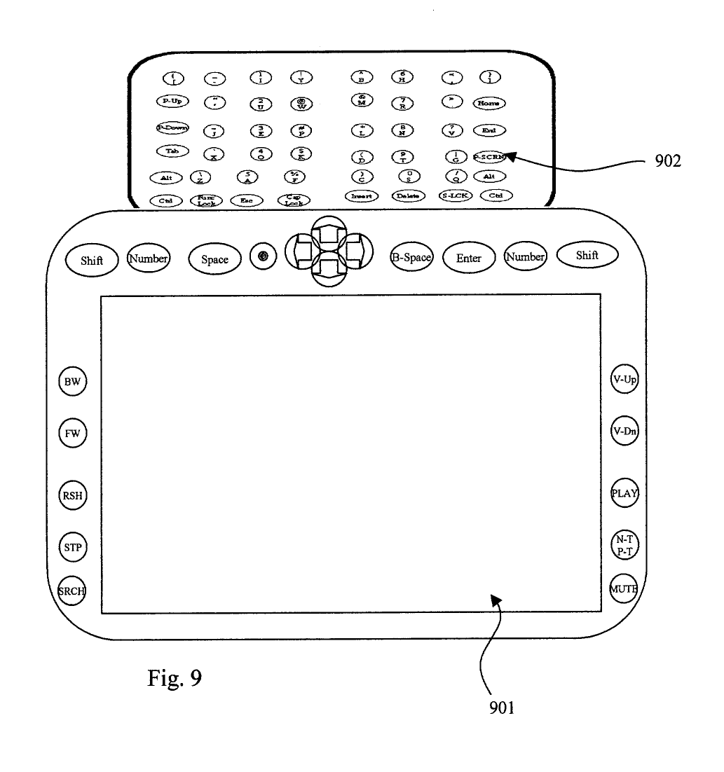

FIG. 9 is an integrated design by combining the keyboard with a PDA. The key mapping card is installed at the top. The card can be pushed into the PDA.

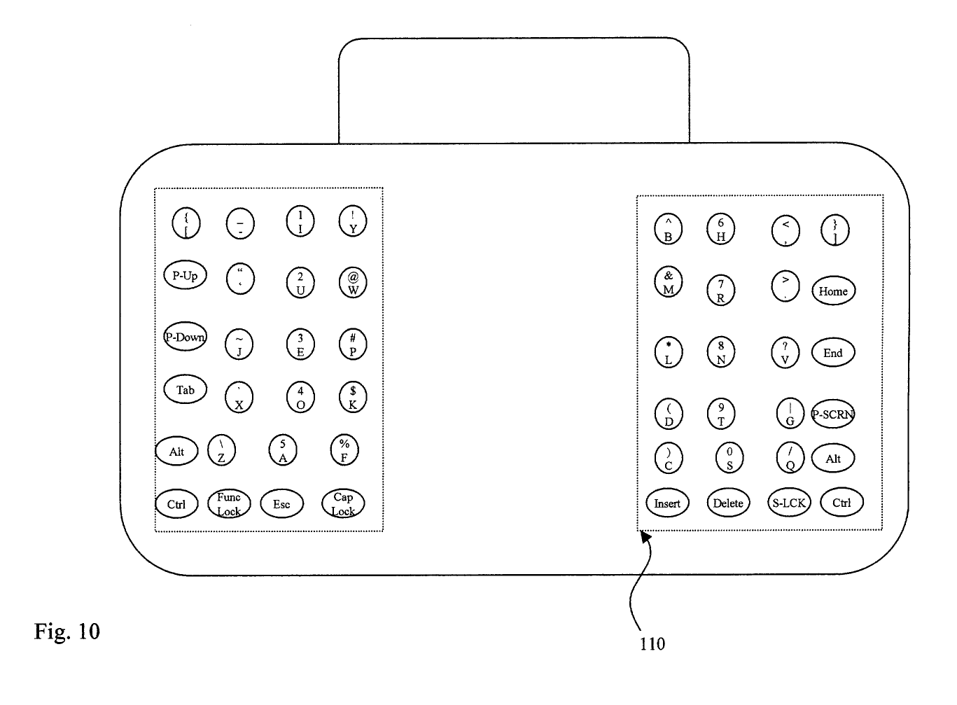

FIG. 10 is the back view of the device in FIG. 9.

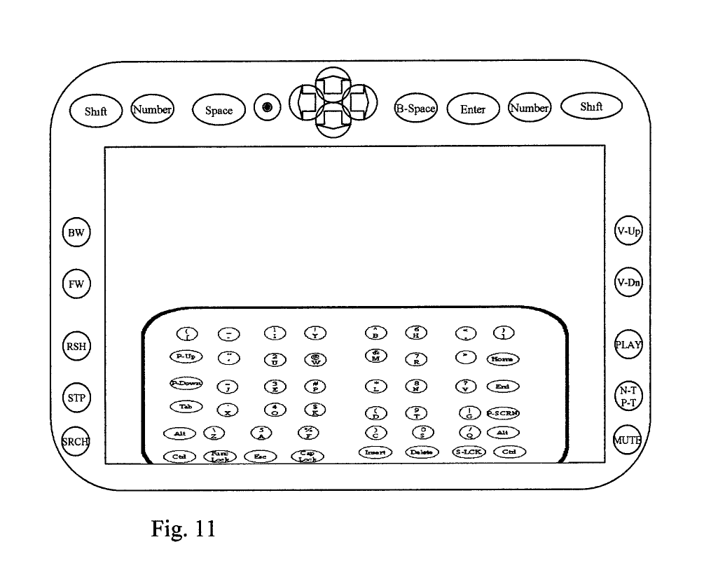

FIG. 11 is an integrated design by combining the keyboard with a PDA. The key mapping card is displayed on the PDA screen.

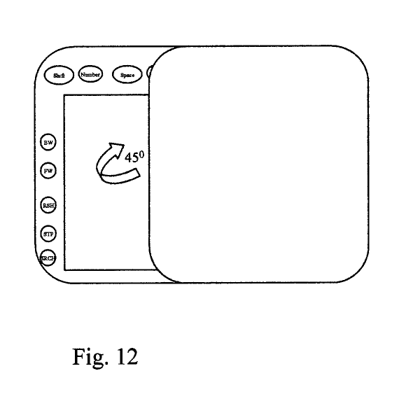

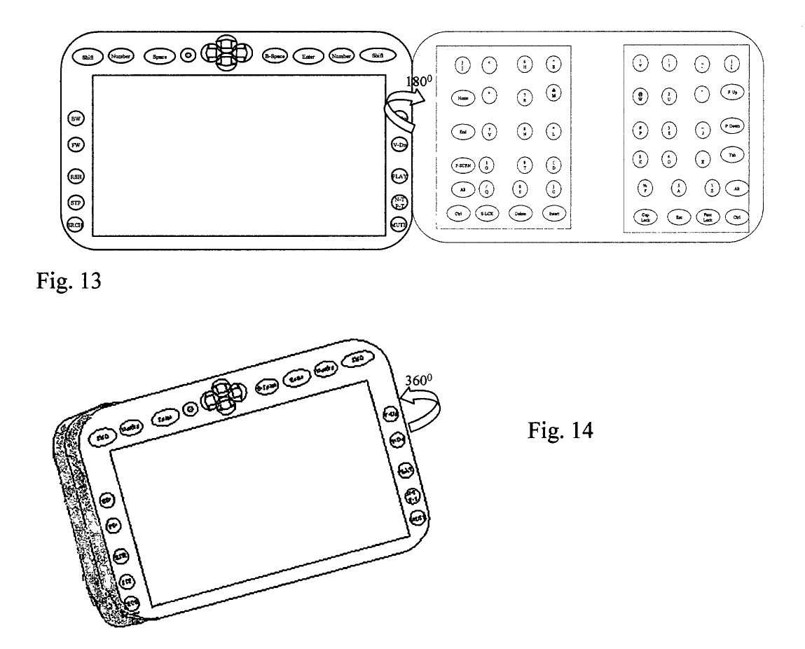

FIG. 12 is different design of the integrated device by combining the keyboard with a PDA. It has covers on top and bottom. The keys and screen are on the insides as shown in FIG. 13.

FIG. 13 is the device shown in FIG. 12. It shows when the said integrated device is open at 180°. In this status, a user can use one hand to operate the device.

FIG. 14 The said integrated device is open at 360° which is ready for two hand operate. The back view is same as FIG. 11.

### DETAILED DESCRIPTION OF THE INVENTION

FIG. 1 and FIG. 2 show the design. There are four major parts of the device:

First part: the boy of the keyboard 100 in FIG. 1. There are electronic circuits, micro chips, and other components inside the body 100 to make the keyboard functional.

Second part: the keys on front and side of the body such as 102 and 103 in FIG. 1. The front keys, in general, are controlled by thumbs. The side keys can be controlled by index fingers or other fingers.

Third part: The keys on the back of the said body 100. In general, these keys are controlled by non thumb fingers.

Fourth part: the key mapping card 101 in FIG. 1, which is on the front of the body. This is a critical part of the keyboard, it helps users to find the keys on the back of the body. Since there are so many keys, it is impossible for a regular user to remember all the association between alphanumeric characters and keys, a key component of the said device is the key map card, which tells the association between alphanumeric characters and keys. It can be easily read when the said device is in use. It is even more convenient than the traditional keyboard because some keys on the traditional keyboard are covered by fingers.

Fifth part: The strips 104 and 106 in FIG. 1 can help user to hold the said device.

The map card 101 in FIG. 1 itself can be an input device same as a small key pad. In case a user can only use one hand, he/she can put the said device face up and use one hand to operate it.

The thumb rest area 110 in FIG. 1 is for thumbs to rest when non-thumb fingers are typing. This provides force to balance the pushing force that non-thumb fingers create when they are typing.

To reduce number of keys on the thumb side in FIG. 1, there are several functions paired on the same keys, they are Page Up and Page Down (P-Up/Down key), Insert and Delete, End and Home. The alternate functions are controlled by SHIFT key.

FIG. 2 is side view of the said keyboard in FIG. 1. There are keys on sides of the said keyboard for various purposes.

FIG. 3 is the back view of the said device. Row 303 is the home key row for left hand, and row 308 is the home key row for right hand. Row 304 and 307 are finger forward rows, and 302, 312 are finger backward rows. Row 330 and 332 are controlled by right hand index finger. Row 320 and 322 are controlled by left hand index finger. Row 334 are controlled by right hand middle finger. Row 324 are controlled by left hand middle finger. Row 336 are controlled by right hand ring finger. Row 326 are controlled by left hand ring finger. Row 338 are controlled by right hand little finger. Row 328 are controlled by left hand little finger. The row 301, 305, 306, and 315 hold keys which are rarely used. Therefore, these rows are not as important as the home, forward, and backward rows.

Once the “Func Lock” key in FIG. 3 is activated, the number keys on row 305 and 306 become function keys same as F1, F2, . . . , F10.

The said keyboard in FIG. 1 can be used for PDA, desktop computer, interactive TV, etc. The said 3D input devices can be connected by cable or wirelessly.

A said 3D keyboard which middle part 401 is open for holding a PDA is depicted in FIG. 4. The key mapping card is separated into two parts 402 and 403. PDA connector has two parts 405 and 407, which is used to connect to a PDA and to hold on a PDA. Part 405 is the base for plug 407. Base 405 has a socket. Part 407 has two plugs on both sides, one side plug is inserted into the socket of base 407, the other plug is inserted to socket of a PDA Part 407 is customized for different PDAs. The connector can be turned to different angles.

FIG. 5. is the said keyboard shown in FIG. 4 with a PDA mounted.

FIG. 6 is a compact design of the keyboard shown in FIG. 4. The keyboard can be pulled towards left and right sides. Keyboard in FIG. 6 is at fully stretched out status, the middle part is for mounting PDA. FIG. 7 is at slide in status. FIG. 8 is a convertible design of the keyboard FIG. 6. Its size is reduced by 50% when it is folded.

FIG. 9 shows integrated keyboard and PDA. It shows the mapping card 902 is mounted at top of the said device. FIG. 10 is the back view of the said integrated device shown in FIG. 9. Since it is critical to have the key map card, a slot is built in to hold the key map card. The map card can be pulled out once the device is in use. The card can be pushed in the slot for carrying around. This is a true palm size note book which can be used for taking meeting notes, writing e-mail on road, etc.

FIG. 11 shows the said device in FIG. 9 with the mapping card displayed on the screen.

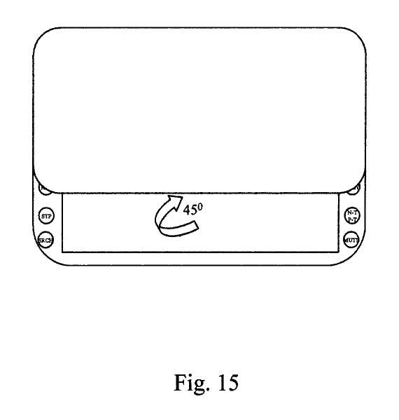

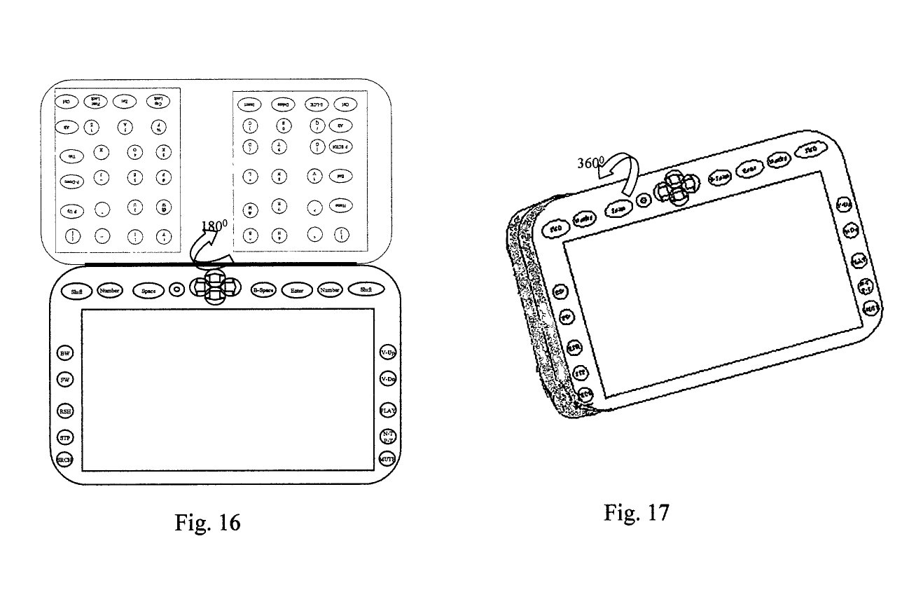

FIGS. 12 to 17 give a different design of the proposed integrated device in FIG. 9. The integrated electronic device according to FIG. 9, wherein there are two separated pads. The thumb controlled keys, mapping card, and screen are placed on one of the said pads. One side of the said pad is used as cover. The non-thumb finger controlled keys are placed on the other one of the said pads. One side of the said pad is used as cover. The two said pads are connected by huoye. When the two said pads are closed to each other, the said electronic device is fully protected by the covers. The two said pads can be opened towards side or towards top. The keys and LCD are not exposed to outside when the two parts are closed. FIG. 12 is at the status when the device is open at 45° angle. The PDA can be opened in two ways. The first one is to open toward right side as shown in FIGS. 12 to 14. FIG. 14 is the operating status after turning the cover by 360°. When it is open at 180°, it can be used for one hand input. FIGS. 15 to 17 show the design open from top.

What is claimed is:

1. An electronic keyboard generate alphanumeric characters and symbols, instructions, and game commands, the said keyboard comprising a key mapping card, buttons/keys and a mouse stick/ball on different sides of the said keyboard, electronic circus, means for connecting to other electronic devices, strips, said keyboard comprising:
a mapping card a printed card or electronic display on a screen. The said mapping card can be in the middle of said keyboard, at top of the said keyboard, or any place of the said keyboard. The said mapping card can be fixed on the surface of the said keyboard, or can be pulled out and pushed into the said keyboard.
different sizes of the keyboard to accommodate different hand sizes.
keys on same side of the said keyboard placed on same or different levels.
means to connect to other electronic devices which can be by wire or wireless.
strips which can be made of soft materials, or hard materials with shape which fits human hands.
the number of keys on different sides ranging from 0 to many.
keys which may have more than one function.
a mapping card which can also be a keyboard.
space and connection device to hold electronic a device such as PDA

2. The keyboard according to claim 1, the said keyboard has moving parts to be pulled out and pushed in with space in the middle for holding electronic device such as PDA when being pulled out, compromising
separated mapping cards divided placed on the different said moving parts.

3. The keyboard according to claim 2, the said keyboard is convertible.

4. The keyboard according to claim 1, the said keyboard is integrated with a hand held electronic device, compromising
a screen in the middle of the said electronic device with the mapping card divided into two parts which are placed on the different sides of the screen.
a screen in the middle of the said electronic device with the mapping card placed at the one edge of the said device, which can be pushed into and be pulled out of the said device.
a screen in the middle of the said electronic device with mapping card displayed on the said screen.
two separated pads, one of which has the thumb controlled keys, mapping card, and screen, and cover on me opposite side of the screen side, and the other said pad hold non-thumb finger controlled keys with cover on one side.
none, one, or two covers with keys and screen inside the covers.
none, one, or two covers which can be opened up to 360°.
